(19) United States
(12) Patent Application Publication
(10) Pub. No.: US 2025/0136812 A1
(43) Pub. Date: May 1, 2025

(54) CURABLE SILICONE COMPOSITION AND CURED PRODUCT THEREOF

(71) Applicants: DuPont Specialty Materials Korea Ltd., Cheonan-si (KR); DuPont Toray Specialty Materials Kabushiki Kaisha, Tokyo (JP)

(72) Inventors: Hyunji Kang, Hwaseong-Si (KR); Shunya Takeuchi, Chiba (JP); Akihiko Kobayashi, Chiba (JP); Kasumi Takeuchi, Chiba (JP); Yuri Iguchi, Tochigi (JP)

(73) Assignees: DuPont Specialty Materials Korea Ltd., Cheonan-si (KR); DuPont Toray Specialty Materials Kabushiki Kaisha, Tokyo (JP)

(21) Appl. No.: 18/931,714

(22) Filed: Oct. 30, 2024

(30) Foreign Application Priority Data
Oct. 31, 2023 (JP) 2023-186552

(51) Int. Cl. C08L 83/04; C08G 77/00; C08G 77/08; C08G 77/12; C08G 77/20; C08G 77/46; C08K 3/22

(52) U.S. Cl. CPC C08L 83/04; C08G 77/08; C08G 77/12; C08G 77/20; C08G 77/46; C08G 77/80; C08K 3/22; C08K 2003/2227; C08L 2203/206; C08L 2205/025; C08L 2205/035

(57) ABSTRACT

The present disclosure provides a curable silicone composition comprising: (A) at least one resinous organopolysiloxane having at least two alkenyl groups and at least one aryl group per molecule; (B) at least one organohydrogen polysiloxane having at least two silicon-bonded hydrogen atoms per molecule; (C) at least one inorganic filler having a reflective index of 1.50 or higher; (D) two or more polyether-modified organopolysiloxane comprising a combination of (d-1) at least one polyether-modified organopolysiloxane having at least one terminal —OH group in a polyether chain, and (d-2) at least one polyether-modified organopolysiloxane having at least one terminal alkoxy or acyloxy group in a polyether chain; and (E) at least one hydrosilylation catalyst. A sealing material formed from the curable silicone composition, and an optical semiconductor device comprising the sealing material are also disclosed.

### CROSS-REFERENCE TO RELATED APPLICATION

This application claims priority to and all benefits of Japanese Patent Application No. 2023-186552, filed Oct. 31, 2023, the content of which is incorporated herein by reference.

### TECHNICAL FIELD

The present disclosure relates to a curable silicone composition suitable for encapsulation of optical semiconductor devices and a cured product thereof.

### BACKGROUND

Curable silicone compositions are utilized in a wide range of industrial fields because they form cured products having excellent heat resistance, cold resistance, electrical insulation, weather resistance, water repellency, and transparency. The cured product of such a curable silicone composition is also suitable as a sealant for optical materials, such as light emitting diodes (LEDs), because it hardly becomes discolored as compared with other organic materials, and there is less deterioration of physical properties, such as durability.

In recent years, various curable silicone compositions have been reported as silicone encapsulants used in optical semiconductor devices such as light emitting diodes (LEDs).
(A) For example, JP-T-2012-507582 discloses a hydrosilylation reaction-curable organopolysiloxane composition comprising: a methylphenylalkenylpolysiloxane that has at least two silicon-bonded alkenyl groups per molecule, wherein diphenylsiloxane units are no more than 5 mole % of the total siloxane units and phenyl groups are at least 20 mole % of the total silicon-bonded organic groups in the molecule, a methylphenylhydrogenpolysiloxane that has at least two silicon-bonded hydrogen atoms per molecule, wherein diphenylsiloxane units are no more than 5 mole % of the total siloxane units and phenyl groups are at least 20 mole % of the total silicon-bonded organic groups in the molecule, and a hydrosilylation reaction catalyst, wherein the diphenylsiloxane units are no more than 5 mole % of the total siloxane units in this composition.

Also, JP-A-2014-159586 discloses a silicone resin composition for coating a light transmitting surface of an optoelectronic device, the composition comprising: a plurality of liquid components including, a linear organopolysiloxane component comprising at least one unsaturated aliphatic group participating in hydrosilylation reaction in a molecule; an organohydrogenpolysiloxane component; and a platinum metal catalyst; said linear organopolysiloxane component having a sufficiently low proportion of organosiloxanes having molecular weights of up to about 1000, such that when said silicone resin product is cured said cured product comprises less than about 10% of said organosiloxanes having molecular weights of up to about 1000.

In addition, JP-A-2017-036416 discloses a curable silicone resin composition comprising a component (A), a component (B), a component (C), a component (D), and a component (E):
(A) a polyorganosiloxane having one or more hydrosilyl groups in a molecule and having no aliphatic unsaturated group;
(B) a hydrosilylation catalyst comprising a platinum group metal;
(C) a branched polyorganosiloxane having one or more alkenyl groups in a molecule;
(D) a silica filler having a mean particle diameter of primary particles of 5-5000 nm; and
(E) a polyether-modified leveling agent.

In addition, JP-A-2020-100683 discloses a curable silicone resin composition comprising a component (A), a component (B), a component (C), and a component (D):
(A) a polyorganosiloxane having one or more hydrosilyl groups in a molecule and having no aliphatic unsaturated group;
(B) a branched polyorganosiloxane having one or more alkenyl groups in a molecule (except for the component (C);
(C) branched polyorganosiloxane having three or more alkenyl groups in a molecule and having a molecular weight of 1000 or less; and
(D) a hydrosilylation catalyst comprising a platinum group metal.

However, since conventional curable silicone compositions may have an insufficient thixotropic property, there may be a problem where an applied curable silicone composition may flow and a cured product having a desired shape may not be obtained even though an appropriate amount of the silicone composition is applied to an optical semiconductor on a support substrate using a dispenser.

Thus, there is a demand for curable silicone compositions which has a high thixotropic property and can provide cured products having a high transparency and a high reflective index for light extraction for optical semiconductor devices.

### SUMMARY OF THE INVENTION

An objective of the present embodiments is to provide a curable silicone composition which possesses a high thixotropic property and can provide cured products having a high transparency and a high reflective index.

The above objective of the present embodiments can be achieved by a curable silicone composition comprising:
(A) at least one resinous organopolysiloxane having at least two alkenyl groups and at least one aryl group per molecule;
(B) at least one organohydrogen polysiloxane having at least two silicon-bonded hydrogen atoms per molecule;
(C) at least one inorganic filler having a reflective index of 1.50 or higher;
(D) two or more polyether-modified organopolysiloxane comprising a combination of (d-1) at least one polyether-modified organopolysiloxane having at least one terminal —OH group in a polyether chain, and (d-2) at least one polyether-modified organopolysiloxane having at least one terminal alkoxy or acyloxy group in a polyether chain; and
(E) at least one hydrosilylation catalyst.

The (A) resinous organopolysiloxane may comprise aryl groups in the silicon atom-bonded organic groups in an amount of 30 mol % or more and 90 mol % or less relative to the total amount of the silicon atom-bonded organic groups.

The (A) resinous organopolysiloxane may consists of D siloxane units represented by (R₂SiO_{2/2}) and T siloxane units represented by (RSiO_{3/2}).

The (B) organohydrogen polysiloxane may comprise at least one aryl group in the silicon atom-bonded organic groups.

The (C) inorganic filler may be selected from aluminium oxides.

The (D) polyether-modified organopolysiloxane including the (d-1) and (d-2) components may be present in a total amount of 0.1% by weight or more and 10% by weight or less, relative to the total weight of the composition.

The present embodiments also relate to a sealing material formed with the curable silicone composition.

The present embodiments also relate to an optical semiconductor device provided with the sealing material.

### DESCRIPTION

The present embodiments provide a curable silicone composition which possesses a high thixotropic property and can provide cured products having a high transparency and a high reflective index.

After diligent research, the inventors have surprisingly discovered that a combination of components (A) to (E) of the present embodiments can provide a curable silicone composition with a good thixotropic property and provide cured products having a high transparency and a high reflective index, and thus completed the present embodiments.

Also, the inventors surprisingly discovered that the silicone curable composition according to the present embodiments possesses a good wettability on a substrate, in particular an organic substrate, which can provide a reliable material for semiconductor devices.

Thus, the composition according to the present embodiments is a curable silicone composition comprising:
(A) at least one resinous organopolysiloxane having at least two alkenyl groups and at least one aryl group per molecule;
(B) at least one organohydrogen polysiloxane having at least two silicon-bonded hydrogen atoms per molecule;
(C) at least one inorganic filler having a reflective index of 1.50 or higher;
(D) two or more polyether-modified organopolysiloxane comprising a combination of (d-1) at least one polyether-modified organopolysiloxane having at least one terminal —OH group in a polyether chain, and (d-2) at least one polyether-modified organopolysiloxane having at least one terminal alkoxy or acyloxy group in a polyether chain; and
(E) at least one hydrosilylation catalyst.

Hereinafter, the composition, process, and use according to the present embodiments will be explained in a more detailed manner.

### Curable Silicone Composition

The curable silicone composition according to the present embodiments comprises (A) at least one resinous organopolysiloxane having at least two alkenyl groups and at least one aryl group per molecule; (B) at least one organohydrogen polysiloxane having at least two silicon-bonded hydrogen atoms per molecule; (C) at least one inorganic filler having a reflective index of 1.5 or higher; (D) two or more polyether-modified organopolysiloxane comprising a combination of (d-1) at least one polyether-modified organopolysiloxane having at least one terminal —OH group in a polyether chain, and (d-2) at least one polyether-modified organopolysiloxane having at least one terminal alkoxy or acyloxy group in a polyether chain; and (E) at least one hydrosilylation catalyst.

Each of the components of the curable silicone composition will be explained below.

### (A) Alkenyl and Aryl Group-Containing Resinous Organopolysiloxane

The curable silicone composition according to the present embodiments comprises at least one resinous organopolysiloxane having at least two alkenyl groups and at least one aryl group per molecule. The composition according to the present embodiments may comprise one type of the (A) alkenyl and aryl group-containing resinous organopolysiloxane or may comprise two or more types of the (A) alkenyl and aryl group-containing resinous organopolysiloxane in combination.

The (A) alkenyl and aryl group-containing organopolysiloxane has a resinous structure. The term “resinous” here means that the organopolysiloxane has a branched or three-dimensional network structure in the molecule. In one embodiment, in the present context, the term “resinous” means that the amount ratio of the total amount of T units and Q units relative to all siloxane units in one molecule of organopolysiloxane is 5% or more, or 10% or more. In general, resinous organopolysiloxane has a viscosity of at least 1 mPa at 25° C. The viscosity of organopolysiloxane components herein can be measured with a rotational viscometer compliant with JIS K7117-1. In addition, in general, resinous organopolysiloxane has a weight-average molecular weight of at least 1,000. The weight-average molecular weight can be measured (in terms of polystyrene) using gel permeation chromatography (GPC).

The alkenyl group included in component (A) may include C₂₋₁₂ alkenyl groups, such as a vinyl, allyl, butenyl, pentenyl, hexenyl, heptenyl, octenyl, nonenyl, decenyl, undecenyl, and dodecenyl groups; and preferably a vinyl group.

The aryl group included in component (A) may include C₆₋₁₂ aryl groups such as phenyl, tolyl, xylyl and naphthyl groups.

Other silicon atom-bonded organic groups other than alkenyl an aryl groups included in component (A) may include C₁₋₁₂ alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl and dodecyl groups; C₇₋₁₂ aralkyl groups such as benzyl, phenethyl, and phenylpropyl groups; and groups obtained by substituting some or all of the hydrogen atoms in these groups with halogen atoms such as fluorine, chlorine or bromine atoms. It should be noted that a small amount of an alkoxy group such as a methoxy or ethoxy group may be bonded to the silicon atom in the component (A), provided that this does not adversely affect the aim of the present embodiments. Preferably, the silicon atom-bonded organic groups other than alkenyl groups comprise a C₁₋₁₂ alkyl group, in particular a methyl group. Component (A) may include no thiol groups or no glycidyl group.

In one embodiment of the present embodiments, the (A) alkenyl and aryl group-containing resinous organopolysiloxane can be represented by the following formula (I-a):

(R¹₃SiO_{1/2})ₐ(R¹₂SiO_{2/2})_{b}(R¹SiO_{3/2})_{c}(SiO_{4/2})_{d}(XO_{1/2})ₑ average unit formula (I-a):

in which, R¹ indicates the same or different monovalent hydrocarbon, which can be optionally substituted with at least one halogen, wherein at least two of R¹ per molecule represent alkenyl groups and at least one of R¹ represents an aryl group; X represents a hydrogen or an alkyl group; and 0≤a<1, 0≤b<1, 0≤c<0.95, 0≤d<0.9, 0≤e<0.4, a+b+c+d=1.0, and c+d>0 are satisfied. A numerical value e indicates a ratio how many (XO_{1/2}) groups are included relative to a total number of silicon atoms.

Here, a formula including siloxane unit represented by SiO_{x/2}, where x indicates an integer from 1 to 4, is expressed as an “average unit formula”, while a formula not including the siloxane unit represented by SiO_{x/2} is expressed as “average structural formula”.

The monovalent hydrocarbon for R¹ in formula (I-a), which can be optionally substituted with at least one halogen, may include, C₁₋₁₂ alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl and dodecyl groups; C₂₋₁₂ alkenyl groups, such as a vinyl, allyl, butenyl, pentenyl, hexenyl, heptenyl, octenyl, nonenyl, decenyl, undecenyl, and dodecenyl groups; C₆₋₁₂ aryl groups such as phenyl, tolyl, xylyl and naphthyl groups; C₇₋₁₂ aralkyl groups such as benzyl, phenethyl, and phenylpropyl groups; and groups obtained by substituting some or all of the hydrogen atoms in these groups with halogen atoms such as fluorine, chlorine or bromine atoms. The monovalent hydrocarbon in R¹ may include a small amount of alkoxy group such as a methoxy or ethoxy group, provided that this does not adversely affect the aim of the present embodiments. Preferably, the monovalent hydrocarbon in R¹ represents a C₁₋₁₂ alkyl group, in particular a methyl group, C₂₋₁₂ alkenyl groups, in particular a vinyl group, or a C₆₋₁₂ aryl group, in particular a phenyl group.

In formula (I-a), X represents a hydrogen or an alkyl group. The alkyl group in X preferably represents a Cia alkyl group such as a methyl, ethyl, or propyl group.

In one embodiment of the present disclosure, in formula (I-a), a ranges preferably from 0≤a≤0.3, more preferably in the range of 0≤a≤0.2, and even more preferably in the range of 0≤a≤0.1. In formula (I-a), b ranges preferably from 0.2≤b≤0.8, more preferably from 0.3≤b≤0.7, and even more preferably from 0.4≤b≤0.6. In formula (I-a), c ranges preferably from 0.2≤c≤0.8, more preferably from 0.3≤c≤0.7, and even more preferably from 0.4≤c≤0.6. In formula (I-a), d ranges preferably from 0≤d≤0.3, more preferably from 0≤d≤0.2, and even more preferably from 0≤d≤0.1. In formula (I-a), e ranges preferably from 0≤e≤0.2, more preferably from 0≤e≤0.1, and even more preferably from 0≤e≤0.05. In formula (I-a), c+d ranges preferably from 0.1≤c+d≤0.8, more preferably from 0.2≤c+d≤0.7, and even more preferably from 0.3≤c+d≤0.6. In the present specification, any combination of an upper numerical limit and a lower numerical limit is available to represent a certain numerical range.

In one embodiment of the present disclosure, in formula (I-a), b is more than 0, i.e., the (A) resinous organopolysiloxane comprises at least one D siloxane unit represented by (R₂SiO_{2/2}).

In one embodiment of the present disclosure, in formula (I-a), c is more than 0, i.e., the (A) resinous organopolysiloxane comprises at least one T siloxane unit represented by (RSiO_{3/2}). In one embodiment, the (A) resinous organopolysiloxane may or may not comprise a Q siloxane unit represented by (SiO_{4/2}), however, it preferably does not comprise any Q units. In one embodiment, the (A) resinous organopolysiloxane may or may not comprise a M siloxane unit represented by (R₃SiO_{1/2}), however, it preferably does not comprise any M units. Here, R in siloxane units indicates an organic group attached to a silicon atom.

In another embodiment of the present disclosure, the (A) alkenyl and aryl group-containing resinous organopolysiloxane comprises at least one resinous organopolysiloxane consisting of D and T units, which can be represented by the following formula (I-b):

(R¹₂SiO_{2/2})ₛ(R¹SiO_{3/2})ₜ (A) average unit formula (I-b):

in which, R¹ indicates the same or different monovalent hydrocarbon, which can be optionally substituted with at least one halogen, wherein at least two of R¹ per molecule represent alkenyl groups and at least one of R¹ represents an aryl group; and 0<s<1, 0<t<1, and s+t=1.0 are satisfied. One type of resinous organopolysiloxane consisting of D and T units or two or more types of resinous organopolysiloxane consisting of D and T units can be used as the Component (A) organopolysiloxane.

The same definition for R¹ in formula (I-a) can be applied to R¹ in formula (I-b).

In one embodiment of the present disclosure, in formula (I-b), s preferably ranges from 0.2≤s≤0.8, more preferably in the range of 0.3≤s≤0.7, and even more preferably in the range of 0.3≤s≤0.6. In formula (I-b), t preferably ranges from 0.2≤t≤0.8, more preferably from 0.3≤t≤0.7, and even more preferably from 0.4≤t≤0.6.

In one embodiment of the present disclosure, the (A) resinous organopolysiloxane comprises alkenyl groups in D siloxane units. The (A) resinous organopolysiloxane may or may not comprise alkenyl groups at M or T siloxane units, however, it preferably does not comprise alkenyl groups at M nor T units.

The amount of the alkenyl groups relative to the total amount of the silicon atom-bonded organic groups in the (A) organopolysiloxane is not particularly limited, but for example 5 mol % or more, preferably 10 mol % or more, more preferably 15 mol % or more, and in general 40 mol % or less, preferably 30 mol % or less, and more preferably 20 mol % or less, relative to the total amount of the silicon atom-bonded organic groups.

The amount of the alkenyl groups can be measured, for example, with analytical methods such as Fourier transform infrared spectroscopy (FT-IR) or nuclear magnetic resonance (NMR), or the following titration method.

In the present specification, any combinations of an upper numerical limit and a lower numerical limit is available to represent a certain numerical range.

The method for quantifying the amount of alkenyl groups in organopolysiloxane by the titration method will be described below. The content of alkenyl groups in organopolysiloxane can be accurately quantified by the titration method known as the Wijs method. The principle is described below. First, alkenyl groups present in organopolysiloxane raw materials and iodine monochlorides are subjected to an addition reaction as shown in Equation (1). Next, by the reaction represented by Equation (2), iodine monochlorides in an excess quantity are reacted with potassium iodides so as to be released as iodines. The free iodines are then titrated with a sodium thiosulfate solution.

CH₂═CH—+2ICl→CH₂I—CHCl—+ICl (excess quantity) Equation (1)

ICl+KI→I₂+KCl Equation (2)

The amount of the alkenyl groups present in the organopolysiloxane can be quantified from the difference between the amounts of sodium thiosulfate required for the titration above and for a blank solution prepared separately.

The (A) resinous organopolysiloxane comprises at least one aryl group in the silicon atom-bonded organic groups. In one embodiment, the (A) resinous organopolysiloxane comprises at least one aryl group at a D unit or T unit. The (A) organopolysiloxane may or may not comprise aryl groups at an M unit, but preferably does not comprise any aryl groups at an M unit.

The content of the aryl groups in the (A) resinous organopolysiloxane is not particularly limited, but in general 30 mol % or more, preferably 40 mol % or more, more preferably 55 mol % or more, and even more preferably 60 mol % or more, and in general 90 mol % or less, preferably 80 mol % or less, more preferably 75 mol % or less, and even more preferably 70 mol % or less, relative to the total amount of the silicon atom-bonded organic groups. The amount of the aryl groups can be measured, for example, with analytical methods such as Fourier transform infrared spectroscopy (FT-IR) or nuclear magnetic resonance (NMR), or the following titration method.

The weight-average molecular weight of the (A) resinous organopolysiloxane is not particularly limited, but is preferably from 1,000 to 100,000, and more preferably from 1,000 to 10,000 and more preferably from 1,500 to 5,000. The weight-average molecular weight can be measured (in terms of polystyrene) using gel permeation chromatography (GPC).

The viscosity of the (A) resinous organopolysiloxane is not particularly limited, but may be for example from 300 mPa to 100,000 mPa at 25° C. On the other hand, the (A) resinous organopolysiloxane may be in a solid form at 25° C. The viscosity of organopolysiloxane components herein can be measured with a rotational viscometer compliant with JIS K7117-1.

The (A) resinous organopolysiloxane may be present in an amount of 1% by weight or more, preferably 10% by weight or more, more preferably 20% by weight or more, and even more preferably 30% by weight or more, and may be present in an amount of 80% by weight or less, preferably 70% by weight or less, and more preferably 50% by weight or less, relative to the total weight of the composition. Any combination of the upper limit and the lower limit is available.

### (B) Organohydrogen Polysiloxane

Component (B) is organohydrogen polysiloxane having at least two silicon atom-bonded hydrogen atoms per molecule. The composition according to the present embodiments may comprise one type of the (B) organohydrogen polysiloxane or may comprise two or more types of the (B) organohydrogen polysiloxane in combination.

The (B) organohydrogen polysiloxane may be linear, branched, partially-branched, cyclic, or resinous. Preferably, the (B) organohydrogen polysiloxane is linear organohydrogen polysiloxane.

Other silicon atom-bonded organic groups other than a hydrogen atom included in component (B) may include a monovalent hydrocarbon other than an alkenyl group, for example, C₁₋₁₂ alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl and dodecyl groups; C₆₋₁₂ aryl groups such as phenyl, tolyl, xylyl and naphthyl groups; C₇₋₁₂ aralkyl groups such as benzyl, phenethyl, and phenylpropyl groups; and groups obtained by substituting some or all of the hydrogen atoms in these groups with halogen atoms such as fluorine, chlorine or bromine atoms. It should be noted that a small amount of alkoxy group such as methoxy or ethoxy group may be bonded to the silicon atom in the component (B), provided that this does not adversely affect the aim of the present embodiments. Preferably, the silicon atom-bonded organic groups other than alkenyl groups comprise a C₁₋₁₂ alkyl group, in particular a methyl group and a C₆₋₁₂ aryl group, in particular a phenyl group.

In one embodiment, the (B) organohydrogen polysiloxane comprises at least one linear organohydrogen polysiloxane which can be represented by the following formula (II):

R²₃SiO(R²₂SiO)ₘSiR²₃ average structural formula (II):

in which, R² indicates the same or different monovalent hydrocarbon other than an alkenyl group, which can be optionally substituted with at least one halogen, wherein at least two of R² per molecule represent hydrogen atoms; and m ranges from 1 to 50. One type of linear organohydrogen polysiloxane or two or more types of linear organohydrogen polysiloxane according to formula (II) can be used as the (B) organohydrogen polysiloxane.

The monovalent hydrocarbon other than an alkenyl group for R² in formula (II), which can be optionally substituted with at least one halogen, may include, C₁₋₁₂ alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl and dodecyl groups; C₆₋₁₂ aryl groups such as phenyl, tolyl, xylyl and naphthyl groups; C₇₋₁₂ aralkyl groups such as benzyl, phenethyl, and phenylpropyl groups; and groups obtained by substituting some or all of the hydrogen atoms in these groups with halogen atoms such as fluorine, chlorine or bromine atoms. The monovalent hydrocarbon in R² may include a small amount of alkoxy group such as a methoxy or ethoxy group, provided that this does not adversely affect the aim of the present embodiments. Preferably, the monovalent hydrocarbon in R² represents a C₁₋₁₂ alkyl group, in particular a methyl group or a C₆₋₁₂ aryl group, in particular a phenyl group.

In formula (II), m preferably ranges from 1 to 25, and more preferably from 1 to 10, and even more preferably ranges from 1 to 5.

In one typical embodiment, the linear organohydrogen polysiloxane according to formula (II) comprises at least one aryl group, preferably a phenyl group, at side chain of the molecule chain. In other words, the linear organohydrogen polysiloxane according to formula (II) may comprise at least one aryl group at D siloxane units represented by (R₂SiO_{2/2}). In another typical embodiment, the linear organohydrogen polysiloxane according to formula (II) comprises at least one (Ar₂SiO_{2/2}) unit where Ar indicates an aryl group, preferably a phenyl group.

In a case that the (B) organohydrogen polysiloxane comprises aryl groups per molecule, the content of the aryl groups in the (B) organohydrogen polysiloxane is not particularly limited, but in general 5 mol % or more, preferably 10 mol % or more, and more preferably 15 mol % or more, and in general 50 mol % or less, preferably 40 mol % or less, and more preferably 30 mol % or less, relative to the total amount of the silicon atom-bonded organic groups. The amount of the aryl groups can be measured, for example, with analytical methods such as Fourier transform infrared spectroscopy (FT-IR) or nuclear magnetic resonance (NMR).

The (B) organohydrogen polysiloxane may be present in an amount of 1% by weight or more, preferably 5% by weight or more, and more preferably 10% by weight or more, and may be present in an amount of 40% by weight or less, preferably 30% by weight or less, and more preferably 20% by weight or less, relative to the total weight of the composition. Any combination of the upper limit and the lower limit is available.

In one embodiment, the (B) organohydrogen polysiloxane can be included in the composition so that the molar ratio of the silicon atom-bonded hydrogen atom derived from the component (B) to the silicon atom-bonded alkenyl groups in the organopolysiloxane components, i.e. H/Vi molar ratio, is 0.6 or more, preferably 0.7 or more, and more preferably 0.75; and/or may be 2.0 or less, preferably 1.6 or less, more preferably 1.4 or less, and even more preferably 1.2 or less.

### (C) High Reflective Inorganic Filler

The composition according to the present embodiments comprises at least one high reflective inorganic filler having at least 1.50 or higher of a reflective index. One type of the (C) high reflective inorganic filler or two or more types of the (C) high reflective inorganic fillers may be used in combination.

The term “filler(s)” should be understood as meaning mineral or synthetic particles of any shape which are insoluble in the medium of the composition.

The (C) high reflective inorganic fillers may be of any shape: platelet-shaped, spherical, or oblong, irrespective of the crystallographic form (for example lamellar, cubic, hexagonal, orthorhombic, etc.). Preferably, the high reflective inorganic fillers are in the shape of a spherical form.

A refractive index of the (C) high reflective inorganic fillers is at least 1.50. Preferably, the refractive index of the (C) high reflective inorganic fillers is 1.55 or higher, more preferably 1.60 or higher, even more preferably 1.65 or higher, and in particular 1.70 or higher. The upper limit of the reflective index is not particularly limited, but is usually 2.0 or less. The refractive index of the (C) inorganic filler can indicate values measured for example at 25° C. and at a wavelength of 589 nm.

The (C) high reflective inorganic fillers may include metal oxides, such as aluminium oxides, zirconium oxides, titanium oxides, zinc oxides, germanium oxides, indium oxides, tin oxides, antimony oxides and cerium oxides; metal hydroxides, such as aluminium hydroxide; nitrides, such as silicon nitride, boron nitride, and aluminium nitride. Preferably, the (C) high reflective inorganic fillers may be selected from aluminium oxides.

The (C) high reflective inorganic fillers may be also selected from metal oxides such as talc, clay, bentonite, and mica. As the commercially available products, mention can be made of GARAMITE® 7305, 7303, 1958, or 2578 from BYK, which are organic-modified bentonite, and Nano Ace® D600/D300 from Nippon talc, which are talc.

The (C) high reflective inorganic fillers may have been subjected to surface hydrophobic treatment with an organosilicon compound such as an organoalkoxysilane compound, organochlorosilane compound, organosilazane compound, or low molecular weight siloxane compound, or silane coupling agent, titanate coupling agent or the like, before it is used in the present embodiments.

The (C) high reflective inorganic fillers may have an average primary particle size of 1 nm or more, and preferably 5 nm or more. The (C) high reflective inorganic fillers may have an average primary particle size of 50 μm or less, and preferably 30 μm or less. The term “average primary particle size” used herein represents a number-average size mean diameter which is given by the statistical particle size distribution to half of the population, referred to as D50. For example, the number-average size mean diameter can be measured by a laser diffraction particle size distribution analyzer.

In one embodiment, the (C) high reflective inorganic fillers has an average primary particle size of 1 μm or less, preferably 200 nm or less, more preferably 50 nm or less, and even more preferably 25 nm or less. Thus, in this embodiment, the average primary particle size of the (C) high reflective inorganic fillers may range from 1 nm to 1 μm μm, from 1 nm to 200 nm, from 5 nm to 50 nm or from 5 nm to 25 nm.

The (C) high reflective inorganic filler may have a specific surface area determined by BET method of 1 m²/g or more, preferably 5 m²/g or more, more preferably 10 m²/g or more, and even more preferably 20 m²/g or more. The (C) high reflective inorganic filler may have a specific surface area determined by BET method of 500 m²/g or less, preferably 300 m²/g or less, and more preferably 250 m²/g or less. In the present disclosure, the “specific surface area determined by BET method” can mean a value determined by: drying a sample for measurement at 200° C. for no less than three hours under a reduced pressure of no more than 1 kPa; thereafter measuring an adsorption isotherm of only nitrogen adsorption at liquid nitrogen temperature; and analyzing the adsorption isotherm by the BET method. The pressure range used for the analysis is a relative pressure of 0.1 to 0.25.

The (C) high reflective inorganic filler may be present in an amount of 1% by weight or more, preferably 2% by weight or more, and more preferably 3% by weight or more, and may be present in an amount of 30% by weight or less, preferably 20% by weight or less, and more preferably 15% by weight or less, relative to the total weight of the composition. Any combination of the upper limit and the lower limit is available.

### (D) Polyether-Modified Organopolysiloxane

The composition according to the present embodiments comprises two or more polyether-modified organopolysiloxane. Specifically, the (D) polyether-modified organopolysiloxane comprises a combination of (d-1) at least one polyether-modified organopolysiloxane having at least one terminal —OH group in a polyether chain, and (d-2) at least one polyether-modified organopolysiloxane having at least one terminal alkoxy or acyloxy group in a polyether chain.

The (D) polyether-modified organopolysiloxane is a side chain and/or terminal polyether-modified organopolysiloxane. In other words, the (D) polyether-modified organopolysiloxane has at least one organic group including at least one polyether structure or at least one polyether unit at a molecular side chain and/or molecular terminal. This means that the (D) organopolysiloxane is an organopolysiloxane in which at least one side chain and/or molecular terminal is modified with at least one polyether structure or polyether unit.

The molecular structure of (D) polyether-modified organopolysiloxane may be linear, branched, partially-branched, cyclic, or resinous, and is preferably linear.

The (d-1) component of the polyether-modified organopolysiloxane is polyether-modified organopolysiloxane having at least one terminal —OH group in a polyether chain. One type of the (d-1) polyether-modified organopolysiloxane or two or more types of the (d-1) polyether-modified organopolysiloxane may be used in combination.

In one embodiment, the (d-1) polyether-modified organopolysiloxane may be linear organopolysiloxane having at least one terminal —OH group in a polyether chain, which can be represented by the following formula (III-a):

R³₃SiO(R³₂SiO)ₘSiR³₃ average structural formula (III-a):

in which, R³ indicates the same or different an organic group including a polyoxyalkylene group having a terminal —OH group or monovalent hydrocarbon which can be optionally substituted with at least one halogen, wherein at least one of R³ per molecule represents an organic group including a polyoxyalkylene group having a terminal —OH group; and m ranges from 1 to 1,000.

The polyoxyalkylene group having a terminal —OH group included in the organic group of R³ in formula (III-a) may include two or more oxyethylene units, oxypropylene units, oxybutylene units, or a combination thereof. The polyoxyalkylene group preferably contains 4 or more, more preferably 6 or more, still more preferably 8 or more oxyalkylene units, and/or 100 or less, preferably 60 or less, more preferably 40 or less, even more preferably 20 or less oxyalkylene units. The alkylene part of the oxyalkylene group may be linear or branched.

The organic group including the polyoxyalkylene group of R³ in formula (I-a) may be represented by the following formula (IV):

—R⁴—O—(C₂H₄O)ₜ₁(C₃H₆O)ₜ₂(C₄H₈O)ₜ₃—OH formula (IV):

in which, R⁴ is a divalent organic group having 1 to 10 carbon atoms, preferably 1 to 5 carbon atoms, which is bonded to a silicon atom; 0≤t1≤60, 0≤t2≤50, 0≤t3≤50, and 2≤t1+t2+t3≤110 are satisfied; and Y is a group selected from a hydrogen atom, an alkyl group having 1 to 4 carbon atoms, and a COCH₃ group.

In formula (IV), R⁴ may represent, for example, an alkylene group, an alkenylene group, or an arylene group, and more specifically, may represent methylene group, ethylene group, propylene group, butylene group, pentylene group, hexylene group, or phenylene group.

In formula (IV), t1, t2, and t3 are the number of oxyethylene units, oxypropylene units, and oxybutylene units constituting the polyoxyalkylene group, and 0≤t1+t2+t3≤110 is satisfied, and preferably 6≤t1+t2+t3≤50, more preferably 8≤t1+t2+t3≤20 is satisfied.

In one embodiment, in formula (IV), t1 is an integer of 2 or more, preferably 4 or more, more preferably 6 or more, even more preferably 8 or more, and is an integer of 50 or less, preferably 30 or less, more preferably 20 or less, and even more preferably 15 or less. In one embodiment, in formula (IV), t2 is an integer of 0 or more and 50 or less, preferably 30 or less, more preferably 10 or less, still more preferably 3 or less. In another embodiment, t2 can be 0. In one embodiment, in formula (IV), t3 is an integer of 0 or more and 50 or less, preferably 30 or less, more preferably 10 or less, still more preferably 3 or less. In another embodiment, t3 can be 0.

In typical embodiments, the polyoxyalkylene groups are selected from polyoxyethylene (POE), linear and/or branched polyoxypropylene (POP), and a combination thereof. The polyether structure may contain at least one polyoxyethylene unit and may comprise only at least one polyoxyethylene unit. In another embodiment, the polyether structure may contain at least one polyoxyethylene (POE) unit and at least one polyoxypropylene (POP) unit in combination.

The monovalent hydrocarbon for R³ in formula (III-a), which can be optionally substituted with at least one halogen, may include, C₁₋₁₂ alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl and dodecyl groups; C₆₋₁₂ aryl groups such as phenyl, tolyl, xylyl and naphthyl groups; C₇₋₁₂ aralkyl groups such as benzyl, phenethyl, and phenylpropyl groups; and groups obtained by substituting some or all of the hydrogen atoms in these groups with halogen atoms such as fluorine, chlorine or bromine atoms. The monovalent hydrocarbon in R³ may include a small amount of hydroxy group or alkoxy group such as a methoxy or ethoxy group, provided that this does not adversely affect the aim of the present embodiments. Preferably, the monovalent hydrocarbon in R³ represents a C₁₋₁₂ alkyl group, in particular a methyl group.

In formula (III-a), m indicates a degree of siloxane polymerization of the polyether-modified linear organopolysiloxane. Preferably, m is 1 or more and 500 or less, more preferably 150 or less, still more preferably 100 or less, even more preferably 50 or less, and particularly preferably 10 or less.

In one embodiment, the (d-1) polyether-modified linear organopolysiloxane having at least one terminal —OH group in a polyether chain may have at least one organic group including an ether bond at molecular terminals, which can be represented by the following formula (III-b):

R⁶R⁵₂SiO(R⁵₂SiO)ₘSiR⁵₂R⁶ average structural formula (III-b):

in which, R⁵ indicates the same or different monovalent hydrocarbon other than an alkenyl group, which can be optionally substituted with at least one halogen; R⁶ indicates an organic group including a polyoxyalkylene group having a terminal —OH group; and m ranges from 0 to 1,000.

The same descriptions about the monovalent hydrocarbon, the organic group including a polyoxyalkylene group having a terminal —OH group, and m for formula (III-a) above can be applied to those for formula (III-b).

In one embodiment, the (d-1) polyether-modified linear organopolysiloxane having at least one terminal —OH group in a polyether chain may have at least one organic group including an ether bond at a molecular side chain, which can be represented by the following formula (III-c):

R⁵₃SiO(R⁵₂SiO)ₘ(R⁵R⁶SiO)ₙSiR⁵₃ average structural formula (III-c):

in which, R⁵ indicates the same or different monovalent hydrocarbon other than an alkenyl group, which can be optionally substituted with at least one halogen; R⁶ indicates an organic group including a polyoxyalkylene group having a terminal —OH group; m ranges from 0 to 1,000; and n ranges from 1 to 1,000.

The same descriptions about the monovalent hydrocarbon, the organic group including a polyoxyalkylene group having a terminal —OH group, and m for formula (III-a) above can be applied to those for formula (III-c).

In formula (III-c), n may be an integer ranging 500 or less, more preferably 150 or less, still more preferably 100 or less, even more preferably 50 or less, and particularly preferably 20 or less.

In one specific embodiment, the (d-1) polyether-modified linear organopolysiloxane can be represented by the following general formula:

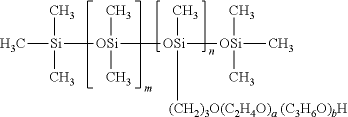

wherein, m ranges from 1 to 1000, preferably from 5 to 500, and n ranges from 1 to 40. Also, a ratio m:n preferably ranges from 200:1 to 1:1. In addition, a ranges from 5 to 50, preferably from 8 to 30, and more preferably from 10 to 20, and b ranges from 0 to 50, preferably from 0 to 50, and more preferably from 0 to 10, and may be 0.

Commercially available examples of the (d-1) organopolysiloxane include the following products:
Product name: BYK-377 (manufactured by BYK), side chain polyether-modified organopolysiloxane having a —OH terminal in the polyether chain, EO/PO ratio in a polyether chain is 10:4.2;
Product name: Silsurf®E608 (manufactured by Siltech), EO-OH terminated linear polyether-modified organopolysiloxane (PEG-8 Dimethicone);
Product name: ABE-3642 (manufactured by Gelest), (30-35% dodecylmethylsiloxane)-[7-10% hydroxy(polyethyleneoxy(6-9)propyl)methylsiloxane]-(55-65% dimethylsiloxane) terpolymer
Product name: Silsurf®Di-15-I (manufactured by Siltech), PO—OH terminated linear polyether-modified organopolysiloxane; and
Product name Silsurf®CR 1115 (manufactured by Siltech), EO/PO polyether-modified linear organopolysiloxane (PEG/PPG 18/18 Diemthicone).

The (d-1) polyether-modified organopolysiloxane may be present in an amount of 0.1% by weight or more, preferably 0.25% by weight or more, and more preferably 0.5% by weight or more, and/or may be present in an amount of 10% by weight or less, preferably 5% by weight or less, and more preferably 3% by weight or less, relative to the total weight of the composition. Any combination of the upper limit and the lower limit is available.

The (d-2) component of the polyether-modified organopolysiloxane is polyether-modified organopolysiloxane having at least one terminal alkoxy or acyloxy group in a polyether chain. One type of the (d-2) polyether-modified organopolysiloxane or two or more types of the (d-2) polyether-modified organopolysiloxane may be used in combination.

The alkoxy group in the polyether chain may include C₁₋₁₀ alkoxyl groups, for example C₁₋₆ alkoxyl groups or C₁₋₄ alkoxyl groups, such methoxy group, ethoxy group, propoxy group, and buthoxy group. The terminal alkoxy group also can be represented by —OR, wherein R indicates C₁₋₁₀ alkyl groups, such as methyl, ethyl, propyl, isopropyl, butyl, isobutyl, and tert-butyl. The alkoxy group is preferably a methoxy group.

The acyloxy group in the polyether chain may include C₁₋₁₀ acyloxy groups, for example C₁₋₆ acyloxy groups or C₁₋₄ acyloxy groups, such acetoxy group. The terminal acyloxy group also can be represented by —O(C═O)R, wherein R indicates C₁₋₁₀ alkyl groups, such as methyl, ethyl, propyl, isopropyl, butyl, isobutyl, and tert-butyl. The acyloxy group is preferably an acetoxy group.

In one embodiment, the (d-2) polyether-modified organopolysiloxane may be linear organopolysiloxane having at least one terminal alkoxy or acyloxy group in a polyether chain, which can be represented by the following formula (V-a):

R⁷₃SiO(R⁷₂SiO)ₘSiR⁷₃ average structural formula (V-a):

in which, R⁷ indicates the same or different an organic group including a polyoxyalkylene group having a terminal alkoxy (or —OR) or acyloxy (or —C(═O)OR) group or monovalent hydrocarbon which can be optionally substituted with at least one halogen, wherein at least one of R⁷ per molecule represents an organic group including a polyoxyalkylene group having a terminal —OR group; and m ranges from 1 to 1,000.

The polyoxyalkylene group having a terminal —OR or —C(═O)OR group included in the organic group of R⁷ in formula (V-a) may include two or more oxyethylene units, oxypropylene units, oxybutylene units, or a combination thereof. The polyoxyalkylene group preferably contains 4 or more, more preferably 6 or more, still more preferably 8 or more oxyalkylene units, and/or 100 or less, preferably 60 or less, more preferably 40 or less, even more preferably 20 or less oxyalkylene units. The alkylene part of the oxyalkylene group may be linear or branched.

The organic group including the polyoxyalkylene group of R⁷ in formula (V-a) may be represented by the following formula (VI-a) or (VI-b):

—R⁴—O—(C₂H₄O)ₜ₁(C₃H₆O)ₜ₂(C₄H₈O)ₜ₃—OR formula (VI-a):

—R⁴—O—(C₂H₄O)ₜ₁(C₃H₆O)ₜ₂(C₄H₈O)ₜ₃—C(═O)OR formula (VI-b):

in which, R⁴ is a divalent organic group having 1 to 10 carbon atoms, preferably 1 to 5 carbon atoms, which is bonded to a silicon atom; 0≤t1≤90, 0≤t2≤80, 0≤t3≤50, and 2≤t1+t2+t3≤170 are satisfied; Y is a group selected from a hydrogen atom, an alkyl group having 1 to 4 carbon atoms, and a COCH₃ group; and R indicates C₁₋₁₀ alkyl groups, such as methyl, ethyl, propyl, isopropyl, butyl, isobutyl, and tert-butyl.

In formulae (VI-a) and (VI-b), R⁴ may represent, for example, an alkylene group, an alkenylene group, or an arylene group, and more specifically, may represent methylene group, ethylene group, propylene group, butylene group, pentylene group, hexylene group, or phenylene group.

In formulae (VI-a) and (VI-b), t1, t2, and t3 are the number of oxyethylene units, oxypropylene units, and oxybutylene units constituting the polyoxyalkylene group, and 0≤t1+t2+t3≤170 is satisfied, and preferably 6≤t1+t2+t3≤160, more preferably 8≤t1+t2+t3≤150 is satisfied.

In one embodiment, in formulae (VI-a) and (VI-b), t1 is an integer of 2 or more, preferably 4 or more, more preferably 6 or more, even more preferably 8 or more, and is an integer of 80 or less, and preferably 75 or less. In one embodiment, in formulae (VI-a) and (VI-b), t2 is an integer of 0 or more and 70 or less, and preferably 65 or less. In another embodiment, t2 can be 0.

In one embodiment, in formulae (VI-a) and (VI-b), t3 is an integer of 0 or more and 50 or less, preferably 30 or less, more preferably 10 or less, still more preferably 3 or less. In another embodiment, t3 can be 0.

In typical embodiments, the polyoxyalkylene groups are selected from polyoxyethylene (POE), linear and/or branched polyoxypropylene (POP), and a combination thereof. The polyether structure may contain at least one polyoxyethylene unit and may comprise only at least one polyoxyethylene unit. In another embodiment, the polyether structure may contain at least one polyoxyethylene (POE) unit and at least one polyoxypropylene (POP) unit in combination.

The monovalent hydrocarbon for R⁷ in formula (V-a) can be the which can be optionally substituted with at least one halogen, may include, C₁₋₁₂ alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl and dodecyl groups; C₆₋₁₂ aryl groups such as phenyl, tolyl, xylyl and naphthyl groups; C₇₋₁₂ aralkyl groups such as benzyl, phenethyl, and phenylpropyl groups; and groups obtained by substituting some or all of the hydrogen atoms in these groups with halogen atoms such as fluorine, chlorine or bromine atoms. The monovalent hydrocarbon in R³ may include a small amount of hydroxy group or alkoxy group such as a methoxy or ethoxy group, provided that this does not adversely affect the aim of the present embodiments. Preferably, the monovalent hydrocarbon in R⁷ represents a C₁₋₁₂ alkyl group, in particular a methyl group.

In formula (V-a), m indicates a degree of siloxane polymerization of the polyether-modified linear organopolysiloxane. Preferably, m is 1 or more and 500 or less, more preferably 150 or less, still more preferably 100 or less, even more preferably 50 or less, and particularly preferably 10 or less.

In one embodiment, the (d-2) polyether-modified linear organopolysiloxane having at least one terminal alkoxy or acyloxy group in a polyether chain may have at least one organic group including an ether bond at molecular terminals, which can be represented by the following formula (V-b):

R⁹R⁸₂SiO(R⁸₂SiO)ₘSiR⁸₂R⁹ (A) average structural formula (V-b):

in which, R⁸ indicates the same or different monovalent hydrocarbon other than an alkenyl group, which can be optionally substituted with at least one halogen; R⁹ indicates an organic group including a polyoxyalkylene group having a terminal —OR or —C(═O)OR group; and m ranges from 0 to 1,000.

The same descriptions about the monovalent hydrocarbon, the organic group including a polyoxyalkylene group having a terminal —OR or —C(═O)OR group, and m for formula (V-a) above can be applied to those for formula (V-b).

In one embodiment, the (d-2) polyether-modified linear organopolysiloxane having at least one terminal alkoxy or acyloxy group in a polyether chain may have at least one organic group including an ether bond at a molecular side chain, which can be represented by the following formula (V-c):

R⁸₃SiO(R⁸₂SiO)ₘ(R⁸R⁹SiO)ₙSiR⁸₃ average structural formula (V-c):

in which, R⁸ indicates the same or different monovalent hydrocarbon other than an alkenyl group, which can be optionally substituted with at least one halogen; R⁹ indicates an organic group including a polyoxyalkylene group having a terminal —OR or —C(═O)OR group; m ranges from 0 to 1,000; and n ranges from 1 to 1,000.

The same descriptions about the monovalent hydrocarbon, the organic group including a polyoxyalkylene group having a terminal —OR or —C(═O)OR group, and m for formula (V-a) above can be applied to those for formula (V-c).

In formula (V-c), n may be an integer ranging 500 or less, more preferably 150 or less, still more preferably 100 or less, even more preferably 50 or less, and particularly preferably 20 or less.

Commercially available examples of the (d-2) organopolysiloxane include the following products:
Product name: EFKA® SL3288 (manufactured by BASF), polyether-terminal modified linear dimethicone having a —OCH₃ terminal in the polyether chain, represented by the formula MeO—(PO)ₘ-(EO)_{m′}-(Me₂SiO)ₙ-(EO)_{m′}—(PO)ₘ—OMe,
Product name KF6011 (manufactured by Shin-Etsu Chemical), side chain PEG-11 methyl ether-modified dimethicone having a —OCH₃ terminal in the polyether chain, represented by the formula Me₃SiO(Me₂SiO)ₘ(Me(POE)SiO)ₙSiMe₃,
Product name SL-3030 (manufactured by BASF), side chain polyether-modified linear dimethicone having a —OCH₃ terminal in the polyether chain represented by the formula Me₃SiO(Me₂SiO)ₙ(Me(POE)(POP)RSiO)ₘSiMe₃.
Product name BYK-378 (manufactured by BYK), EO/PO(1:1) side chain polyether-modified linear dimethicone having a —OC(═O)CH₃ terminal in the polyether chain, represented by the formula Me₃SiO(Me₂SiO)ₙ(Me(POE)(POP)RSiO)ₘSiMe₃.

The number average molecular weights of the (D) polyether-modified organopolysiloxane including components (d-1) and (d-2) is not particularly limited, but may range from 3,000 to 60,000, and preferably from 3,000 to 40,000.

The (d-2) polyether-modified organopolysiloxane may be present in an amount of 0.1% by weight or more, preferably 0.25% by weight or more, and more preferably 0.5% by weight or more, and/or may be present in an amount of 10% by weight or less, preferably 5% by weight or less, and more preferably 3% by weight or less, relative to the total weight of the composition. Any combination of the upper limit and the lower limit is available.

In typical embodiments, the (d-1) polyether-modified organopolysiloxane and the (d-2) polyether-modified organopolysiloxane can be included in the composition so that the weight ratio of the (d-1) polyether-modified organopolysiloxane to the (d-2) polyether-modified organopolysiloxane ranges from 10:1 to 1:10, preferably from 5:1 to 1:5, more preferably from 3:1 to 1:3, and even more preferably from 2:1 to 1:2.

The (D) polyether-modified organopolysiloxane including the (d-1) and (d-2) components may be present in a total amount of 0.1% by weight or more, preferably 0.5% by weight or more, and more preferably 1% by weight or more, and/or may be present in a total amount of 10% by weight or less, preferably 5% by weight or less, and more preferably 3% by weight or less, relative to the total weight of the composition. Any combination of the upper limit and the lower limit is available.

### (E) Curing Catalyst

Component (E) is a curing catalyst that promotes a hydrosilylation reaction of the organopolysiloxane ingredients of the present embodiments. The composition according to the present embodiments may comprise one type of the (E) hydrosilylation catalyst or may comprise two or more types of the (E) hydrosilylation catalysts in combination.

Examples of the hydrosilylation catalyst include platinum based catalysts, rhodium based catalysts, palladium based catalysts, nickel based catalysts, iridium based catalysts, ruthenium based catalysts, and iron based catalysts. Platinum based catalysts are preferable. Examples of the platinum based catalyst include platinum based compounds, such as platinum fine powders, platinum black, platinum-supporting silica fine powders, platinum-supporting activated carbon, chloroplatinic acids, alcohol solutions of chloroplatinic acids, olefin complexes of platinum, alkenylsiloxane complexes of platinum, and the like. Alkenylsiloxane complexes of platinum are particularly preferable. Examples of the alkenylsiloxane include 1,3-divinyl-1,1,3,3-tetramethyldisiloxane, 1,3,5,7-tetramethyl-1,3,5,7-tetravinylcyclotetrasiloxane, alkenylsiloxanes having part of the methyl groups of these alkenylsiloxane substituted by ethyl groups, phenyl groups, or the like, and alkenylsiloxanes having vinyl groups of these alkenylsiloxane substituted by allyl groups, hexenyl groups, or the like.

The amount of the (E) hydrosilylation catalyst used is an effective amount and is not particularly limited. For example, the (E) hydrosilylation catalyst may be present in an amount of 0.1 ppm more, preferably 1 ppm or more, and more preferably 2 ppm or more, and/or may be present in an amount of 20 ppm or less, preferably 15 ppm or less, and more preferably 10 ppm or less, relative to the total weight of the (E) curing reactive organopolysiloxane. Any combination of the upper limit and the lower limit is available.

### Other Organopolysiloxane

In one embodiment, the curable silicone composition may or may not comprise at least one alkenyl group containing linear organopolysiloxane. The alkenyl group containing-linear organopolysiloxane comprises at least two alkenyl groups per molecule, which can be represented by the following formula (VII):

R¹₃SiO(R¹₂SiO)ₘSiR¹₃ (A) average structural formula (VII):

in which, R¹ indicates the same or different monovalent hydrocarbon, which can be optionally substituted with at least one halogen, wherein at least two of R¹ per molecule represent alkenyl groups; and m ranges from 1 to 1,000. One type of linear organopolysiloxane or two or more types of linear organopolysiloxane can be included in the curable silicone composition.

The same definition for R¹ in formula (I-a) can be applied to R¹ in formula (VII).

In formula (VII), m preferably ranges from 5 to 500, more preferably from 10 to 100, and even more preferably ranges from 15 to 50.

In typical embodiments, the alkenyl group containing-linear organopolysiloxane can be linear dimethylpolysiloxane comprising dimethylvinylsiloxy groups at both ends of the molecular chain.

The alkenyl group containing-linear organopolysiloxane may comprise at least one aryl group in the silicon atom-bonded organic groups. In typical embodiments, the alkenyl group containing-linear organopolysiloxane comprises at least one aryl group at a D unit, i.e. at side chain. The alkenyl group containing-linear organopolysiloxane may or may not comprise aryl groups at an M unit, i.e., at molecular terminals, but preferably does not comprise any aryl groups at an M unit.

The content of the aryl groups in the alkenyl group containing-linear organopolysiloxane is not particularly limited, but in general 10 mol % or more, preferably 20 mol % or more, and more preferably 30 mol % or more, and/or in general 70 mol % or less, preferably 60 mol % or less, and more preferably 50 mol % or less, relative to the total amount of the silicon atom-bonded organic groups. The amount of the aryl groups can be measured, for example, with analytical methods such as Fourier transform infrared spectroscopy (FT-IR) or nuclear magnetic resonance (NMR), or the following titration method.

The alkenyl group containing-linear organopolysiloxane may be present in an amount of 5% by weight or more, preferably 10% by weight or more, and more preferably 15% by weight or more, and/or may be present in an amount of 50% by weight or less, preferably 40% by weight or less, and more preferably 30% by weight or less, relative to the total weight of the composition. Any combination of the upper limit and the lower limit is available.

In another embodiment, the curable silicone composition may or may not comprise at least one epoxy group-containing resinous organopolysiloxane. The epoxy group-containing resinous organopolysiloxane can be represented by the following formula (VIII):

(R¹⁰₃SiO_{1/2})ₐ(R¹⁰₂SiO_{2/2})_{b}(R¹⁰SiO_{3/2})_{c}(SiO_{4/2})_{d}(XO_{1/2})ₑ average structural formula (VIII):

in which, R¹⁰ indicates the same or different monovalent hydrocarbon, which can be optionally substituted with at least one halogen, wherein at least two of R¹⁰ per molecule represent alkenyl groups and at least one of R¹⁰ per molecule represents an epoxy group-containing organic group; X represents a hydrogen or an alkyl group; and 0≤a<1, 0≤b<1, 0≤c<0.95, 0≤d<0.9, 0≤e<0.4, a+b+c+d=1.0, and c+d>0 are satisfied. A numerical value e indicates a ratio how many (XO_{1/2}) groups are included relative to a total number of silicon atoms. One type of epoxy group-containing resinous organopolysiloxane or two or more types of epoxy group-containing resinous organopolysiloxane can be used.

The same definition for monovalent hydrocarbon for R¹ in formula (I-a) can be applied to the monovalent hydrocarbon for R¹⁰ in formula (VIII).

The epoxy group-containing organic group for R¹⁰ in formula (VIII) includes glycidoxyalkyl groups, such as 2-glycidoxyethyl group, 3-glycidoxypropyl group, and 4-glycidoxybutyl group; epoxycycloalkyl groups, such as 2-(3,4-epoxycyclohexyl) ethyl group, 3-(3,4-epoxycyclohexyl)-propyl group; epoxyalkyl groups, such as 3,4-epoxybutyl group and 7,8-epoxyoctyl group; and groups obtained by substituting some or all of the hydrogen atoms in these groups with halogen atoms such as fluorine, chlorine or bromine atoms.

Preferably, R¹⁰ in formula (VIII) represents a C₁₋₁₂ alkyl group, in particular a methyl group, C₂₋₁₂ alkenyl groups, in particular a vinyl group, a C₆₋₁₂ aryl group, in particular a phenyl group, and glycidoxyalkyl groups, in particular 3-glycidoxypropyl group.

In formula (VIII), X represents a hydrogen or an alkyl group. The alkyl group in X preferably represents a C₁₋₃ alkyl group such as a methyl, ethyl, or propyl group.

In one embodiment, in formula (VIII), a ranges preferably from 0≤a≤0.4, more preferably in the range of 0.05≤a≤0.3, and even more preferably in the range of 0.1≤a≤0.2. In formula (VIII), b ranges preferably from 0.1≤b≤0.5, more preferably from 0.15≤b≤0.4, and even more preferably from 0.2≤b≤0.3. In formula (VIII), c ranges preferably from 0.1≤c≤0.7, more preferably from 0.2≤c≤0.6, and even more preferably from 0.3≤c≤0.55. In formula (VIII), d ranges preferably from 0≤d≤0.3, more preferably from 0≤d≤0.2, and even more preferably from 0≤d≤0.1. In formula (VIII), e ranges preferably from 0≤e≤0.4, more preferably from 0.05≤e≤0.3, and even more preferably from 0.1≤e≤0.2.

The epoxy group-containing resinous organopolysiloxane may be present in an amount of 0.5% by weight or more, preferably 1% by weight or more, and more preferably 1.5% by weight or more, and/or may be present in an amount of 10% by weight or less, preferably 7% by weight or less, and more preferably 5% by weight or less, relative to the total weight of the composition. Any combination of the upper limit and the lower limit is available.

### Other Ingredients

The curable silicone composition may comprise a hydrosilylation-reaction inhibitor as an additional component. One type of the hydrosilylation-reaction inhibitor or two or more types of hydrosilylation-reaction inhibitors may be used.

As the hydrosilylation-reaction inhibitor, mention can be made of acetylenic alcohols such as methyl butynol, ethynyl cyclohexanol, dimethyl hexynol, 3,5-dimethyl-1-hexyn-3-ol, 1-butyn-3-ol, 1-propyn-3-ol, 2-methyl-3-butyn-2-ol, 3-methyl-1-butyn-3-ol, 3-methyl-1-pentyn-3-ol, 3-phenyl-1-butyn-3-ol, 4-ethyl-1-octyn-3-ol, 1-ethynyl-1-cyclohexanol, and combinations thereof; cycloalkenylsiloxanes such as methylvinylcyclosiloxanes exemplified by 1,3,5,7-tetramethyl-1,3,5,7-tetravinylcyclotetrasiloxane, 1,3,5,7-tetramethyl-1,3,5,7-tetrahexenylcyclotetrasiloxane, and a combination thereof; ene-yne compounds such as 3-methyl-3-penten-1-yne, 3,5-dimethyl-3-hexen-1-yne; triazoles such as benzotriazole; phosphines; mercaptans; hydrazines; amines, such as tetramethyl ethylenediamine, dialkyl fumarates, dialkenyl fumarates, dialkoxyalkyl fumarates, maleates such as diallyl maleate; nitriles; ethers; carbon monoxide; alkenes such as cyclo-octadiene, divinyltetramethyldisiloxane; alcohols such as benzyl alcohol; and a combination thereof. Alternatively, the hydrosilylation-reaction inhibitor may be selected from a group consisting of acetylenic alcohols (e.g., 1-ethynyl-1-cyclohexanol) and maleates (e.g., diallyl maleate, bis maleate, or n-propyl maleate) and a combination of two or more thereof.

The amount of the hydrosilylation-reaction inhibitor present in the curable silicone composition may be 0% to 5% by weight, preferably 0.001% to 3% by weight, and more preferably 0.005% to 1% by weight, relative to the total weight of the composition.

The curable silicone composition according to the present embodiments may also comprise any optional additive(s) usually used in the field, chosen, for example, from organopolysiloxanes other than components as described above, organic fillers, inorganic fillers other than the component (C) above, pigments, adhesion-imparting agents, resistance imparting agent, releasing agents, heat resistance agents, dyes, flame retardancy imparting agents, and mixtures thereof.

The curable silicone composition according to the present embodiments can be prepared by mixing the above-described essential and optional components in a conventional manner. The mixing method of each components can be conducted with a conventionally known method and is not particularly limited. For example, the mixing is carried out by simple stirring or mixing using a mixing device, such as a uniaxial or biaxial continuous mixer, a double roll, a Hobart mixer, a dental mixer, a planetary mixer, a kneader mixer, and a Henschel mixer.

The curable silicone composition according to the present embodiments may have a viscosity ranging from 3 to 50 Pa·s, preferably from 5 to 40 Pa·s, and more preferably from 10 to 30 Pa·s, and even more preferably from 12 to 35 Pa·s at 25° C. The viscosity herein can be measured with a rheometer from Antonpaar with 40 mm cone plate at 2 degree angle at a shear rate of 10/s.

The curable silicone composition according to the present embodiments can be cured to form a cured product having good transparency. Specifically, the cured product of the curable silicone composition of the present embodiments preferably has a light transmittance of 70% or more, more preferably 80% or more, and more preferably 85% or more at a wavelength of 400 nm to 700 nm, for example, at 450 nm. The light transmittance of the cured product can be determined, for example, by measuring the cured product having an optical path length of 1 with a spectrophotometer.

The curable silicone composition according to the present embodiments can be used to encapsulate or seal a semiconductor element including an optical semiconductor in manufacturing semiconductor devices. In this embodiment, the curable silicone composition can be applied to a substrate, for example, selected from a glass substrate and PCB substrate, such as those made of epoxy resin-based polymer. The glass substrate may be surface-coated or not coated with a well-known surface treatment agent, such as silicone surface treatment agents.

### Sealing Material

The present embodiments also relate to a sealing material obtained by curing the curable silicone composition. The sealing material of the present embodiments is preferably used for sealing a semiconductor element including an optical semiconductor. The shape of the sealing material is not limited, but preferably is a dome shape, a lens shape, or a sheet form. Examples of the semiconductor element include SiC, GaN, and the like. Examples of the optical semiconductor element include elements represented by light-emitting diodes (LEDs), photo diodes, photo transistors, laser diodes, and the like.

The substrate on which the sealing material of the present embodiments is formed, is not particularly limited, but, for example, the substrate may be selected from a glass substrate and PCB substrate. The glass substrate may be surface-coated or not coated with a well-known surface treatment agent, such as silicone surface treatment agents.

### Optical Semiconductor Device

The present embodiments also relate to an optical semiconductor device provided with the sealing material. Examples of the optical semiconductor element include a light emitting diode (LED), a semiconductor laser, a photodiode, a phototransistor, a solid-state imaging device, and a light emitting body and a light receiving body for a photocoupler, and a light emitting diode (LED) is particularly preferable.

Since the light emitting diode (LED) emits light from the top, bottom, left, and right of the optical semiconductor element, it is preferable that the parts constituting the light emitting diode (LED) have a high light transmittance. As the substrate on which such an optical semiconductor element is mounted, mention can be made of conductive metals such as silver, gold, and copper; non-conductive metals such as aluminum and nickel; thermoplastic resins, containing white pigments, such as PPA and LCP; thermosetting resins containing white pigments, such as epoxy resins, BT resins, polyimide resins, and silicone resins; ceramics such as alumina and alumina nitride.

The specific aspects according to the present embodiments are shown as below.

Aspect 1: a curable silicone composition comprising:
(A) at least one resinous organopolysiloxane having at least two alkenyl groups and at least one aryl group per molecule;
(B) at least one organohydrogen polysiloxane having at least two silicon-bonded hydrogen atoms per molecule;
(C) at least one inorganic filler having a reflective index of 1.50 or higher;
(D) two or more polyether-modified organopolysiloxane comprising a combination of (d-1) at least one polyether-modified organopolysiloxane having at least one terminal —OH group in a polyether chain, and (d-2) at least one polyether-modified organopolysiloxane having at least one terminal alkoxy or acyloxy group in a polyether chain; and
(E) at least one hydrosilylation catalyst.

Aspect 2: the composition according to Aspect 1, wherein the (A) resinous organopolysiloxane comprises aryl groups in the silicon atom-bonded organic groups in an amount of 30 mol % or more and 90 mol % or less relative to the total amount of the silicon atom-bonded organic groups.

Aspect 3: the composition according to Aspect 1 or 2, wherein the (A) resinous organopolysiloxane consists of D siloxane units represented by (R₂SiO_{2/2}) and T siloxane units represented by (RSiO_{3/2}).

Aspect 4: the composition according to any one of Aspects 1 to 3, wherein the (B) organohydrogen polysiloxane comprises at least one aryl group in the silicon atom-bonded organic groups.

Aspect 5: the composition according to any one of Aspects 1 to 4, wherein the (C) inorganic filler is selected from aluminium oxides.

Aspect 6: the composition according to any one of Aspects 1 to 5, wherein the (D) polyether-modified organopolysiloxane including the (d-1) and (d-2) components is present in a total amount of 0.1% by weight or more and 10% by weight or less, relative to the total weight of the composition.

Aspect 7: a sealing material formed with the curable silicone composition according to any one of Aspects 1 to 6.

Aspect 8: an optical semiconductor device provided with the sealing material according to Aspect 7.

### Examples

The present embodiments will be described in more detail by way of examples which however should not be construed as limiting the scope of the present invention.

The curable silicone compositions of the present embodiments will be described in detail by examples and comparative examples. In the examples and comparative examples, the following components were used to prepare the curable silicone compositions. In the formulae, Vi indicates a vinyl group, Me indicates a methyl group, Ph indicates a phenyl group, and Ep indicates a 3-glycidoxypropyl group. In addition, the chemical formula of the organopolysiloxane component is shown in a simplified manner in the table, and the organic groups other than Me in M, D, or T units are shown in parentheses. The numerical values for the amounts of the components shown in the tables are all based on “part by weight” as active raw materials.

### Components:

(a-1): alkenyl group-containing resinous organopolysiloxane represented by the formula (MeViSiO_{2/2})_{0.28}(Ph₂SiO_{2/2})_{0.23}(PhSiO_{3/2})_{0.49}.
(a-2): alkenyl group-containing resinous organopolysiloxane represented by the formula (MeViSiO_{2/2})_{0.25}(Ph₂SiO_{2/2})_{0.3}(PhSiO_{3/2})_{0.45}
(a-3): alkenyl group-containing linear organopolysiloxane represented by the formula: ViMe₂SiO(MePhSiO)₂₀SiMe₂Vi
(a-4): alkenyl group and epoxy group-containing resinous organopolysiloxane represented by the formula (Me₂ViSiO_{1/2})_{0.13}(MeEpSiO_{2/2})_{0.24}(PhSiO_{3/2})_{0.46}(OMe)_{0.17}
(b): linear organohydrogen polysiloxane represented by the formula HMe₂SiO(Ph₂SiO)SiMe₂H
(c): alumina filler (D50: 10 to 20 nm)
(d-1-1): side chain polyether-modified organopolysiloxane having a —OH terminal in the polyether chain (Product name: BYK-377 sold by BYK), represented by the formula Me₃SiO(Me₂SiO)ₙ(Me(EO)ₘ(PO)_{m′}OHMeSiO)ₘSiMe₃
(d-1-2): polyether chain-terminated organopolysiloxane represented by the formula HO(PO)ₘ(EO)_{m′}Me₂SiO(Me₂SiO)ₜSiMe₂(EO)ₙ(PO)_{n′}OH (Product name Silsurf®E608 sold by Siltech))
(d-2-1): EO/PO polyether-terminated linear organopolysiloxane represented by the formula MeO(PO)ₘ(EO)_{m′}(Me₂SiO)ₙ(EO)_{m′}(PO)ₘOMe (Product name EFKA® SL-3288 sold by BASF)
(d-2-2): side chain PEG-11 methyl ether-modified dimethicone having a —OCH₃ terminal in the polyether chain, represented by the formula Me₃SiO(Me₂SiO)ₘ(Me(POE)SiO)ₙSiMe₃, Product name KF6011 (manufactured by Shin-Etsu Chemical)
(d-2-3): side chain polyether modified linear dimethicone having a —OCH₃ terminal in the polyether chain represented by the formula Me₃SiO(Me₂SiO)ₙ(Me(POE)(POP)RSiO)ₘSiMe₃, Product name SL-3030 (manufactured by BASF),
(d-2-4): side chain polyether modified linear dimethicone having a —OC(═O)CH₃ terminal in the polyether chain, represented by the formula Me₃SiO(Me₂SiO)ₙ(Me(POE)(POP)RSiO)ₘSiMe₃, Product name BYK-378 (manufactured by BYK), EO/PO(1:1)
(e): complex of platinum and 1,3-divinyl-1,1,3,3-tetramethyldisiloxane (platinum concentration: 3.0% by weight)
(f): 1-ethyneyl-1-cyclohexanol.

### Evaluation

### Viscosity and Thixotropic Property

The viscosity of the prepared curable silicone composition of each of the examples was measured with a rheometer (Antonpaar MCR302) with 40 mm cone plate at 2 degree angle at a shear rate of 10/s and 1/s at 25 EC. Thixotropic index was calculated as a viscosity ratio of(viscosity at s)/(viscosity at 10/s).

### Refractive Index

A refractive index of the curable silicone composition at 25° C. was measured with an Abbe type refractive index meter at a wave length of 589 nm.

### Transmittance

The curable silicone composition was filled into a mold having a concavity with a predetermined shape and was then cured at 150° C. for 60 minutes. The obtained plate-like cured product having a thickness of 1 mm was subjected to transmittance measurement at 450 nm at 25° C.

### Wettability on PCB

The curable silicone composition was dispensed on a PCB substrate made of epoxy resin based polymer so as to form a straight line shape having a height of about 1 mm. After leaving the composition for 3 hours at 25° C., the dispensed curable silicone composition was then cured at 150° C. for 60 minutes. The wettability on the PCB substrate was analyzed by observing whether or not there is a delamination between the cured composition and the PCB substrate. When there was no delamination, the result is shown as “OK”, while there was a delamination, it is shown as “NG”.

The results are summarized in the tables below.

TABLE 1

| Components | Ex. 1 | Ex. 2 | Ex. 3 | Ex. 4 | Ex. 5 | Ex. 6 | Ex. 7 |
|---|---|---|---|---|---|---|---|
| a-1 D(Vi)₂₈—D(Ph₂)₂₃—T(Ph)₄₉ | 49 | 49 | 49 | 49 | 49 | 49 | 49 |
| a-3 M(Vi)—D(Ph²)₂₀—M(Vi) | 24.1 | 24.1 | 24.1 | 24.1 | 24.1 | 24.1 | 24.1 |
| a-4 M(Vi)₁₃—D(Ep)₂₄—T(Ph)₄₆—(OMe)₁₇ | 2.5 | 2.5 | 2.5 | 2.5 | 2.5 | 2.5 | 2.5 |
| b M(H)—D(Ph₂)—M(H) | 16.38 | 16.38 | 16.38 | 16.38 | 16.38 | 16.38 | 16.38 |
| c Al₂O₃ (D50: 10 to 20 nm) | 7 | 7 | 7 | 7 | 7 | 7 | 7 |
| d-1-1 BYK-377 | 1 | 1 | 1 | 1 | — | — | — |
| d-1-2 Silsurf ®E608 | — | — | — | — | 1 | 1 | 1 |
| d-2-1 EFKA ® SL-3288 | 1 | — | — | — | 1 | — | — |
| d-2-2 KF6011 | — | 1 | — | — | — | 1 | — |
| d-2-3 SL3030 | — | — | 1 | — | — | — | 1 |
| d-2-4 BYK-378 | — | — | — | 1 | — | — | — |
| f 1-Ethyneyl-1-Cyclohexanol | 0.02 | 0.02 | 0.02 | 0.02 | 0.02 | 0.02 | 0.02 |
| Total | 101 | 101 | 101 | 101 | 101 | 101 | 101 |
| e (Pt, ppm) | 6 | 6 | 6 | 6 | 6 | 6 | 6 |
| H/Vi ratio (mole) | 0.8 | 0.8 | 0.8 | 0.8 | 0.8 | 0.8 | 0.8 |
| Evaluation | | | | | | | |
| Viscosity (Pa · s @ 25° C., 1/s) | 52 | 48 | 55 | 51 | 50 | 44 | 47 |
| Viscosity (Pa · s @ 25° C., 10/s) | 18 | 16 | 18 | 17 | 17 | 15 | 16 |
| Thixotropic index | 2.95 | 3 | 3 | 3 | 2.94 | 3 | 3 |
| Refractive index | 1.55 | 1.55 | 1.55 | 1.55 | 1.55 | 1.55 | 1.55 |
| Transmittance (%) | 80 | 81 | 81 | 81 | 88 | 85 | 85 |
| Wettability on PCB | OK | OK | OK | OK | OK | OK | OK |

TABLE 2

| | | | Comp. | Comp. | Comp. | Comp. |
|---|---|---|---|---|---|---|
| Components | Ex. 8 | Ex. 9 | Ex. 1 | Ex. 2 | Ex. 3 | Ex. 4 |
| a-1 D(Vi)₂₈—D(Ph₂)₂₃—T(Ph)₄₉ | 49 | — | 49 | 49 | 49 | 49 |
| a-2 D(Vi)₂₅—D(Ph₂)₃₀—T(Ph)₄₅ | — | 49 | — | — | — | — |
| a-3 M(Vi)—D(Ph²)₂₀—M(Vi) | 24.1 | 24.1 | 24.1 | 24.1 | 24.1 | 24.1 |
| a-4 M(Vi)₁₃—D(Ep)₂₄—T(Ph)₄₆—(OMe)₁₇ | 2.5 | 2.5 | 2.5 | 2.5 | 2.5 | 2.5 |
| b M(H)—D(Ph₂)—M(H) | 16.38 | 16.38 | 16.38 | 16.38 | 16.38 | 16.38 |
| c Al₂O₃ (D50: 10 to 20 nm) | 7 | 7 | 7 | 7 | 7 | 7 |
| d-1-1 BYK-377 | — | — | 1 | — | — | — |
| d-1-2 Silsurf ®E608 | 1 | 1 | — | 1 | — | — |
| d-2-1 EFKA ® SL-3288 | — | 1 | — | — | 1 | — |
| d-2-4 BYK-378 | 1 | — | — | — | — | — |
| f 1-Ethyneyl-1-Cyclohexanol | 0.02 | 0.02 | 0.02 | 0.02 | 0.02 | 0.02 |
| Total | 101 | 101 | 100 | 100 | 100 | 99 |
| e (Pt, ppm) | 6 | 6 | 6 | 6 | 6 | 6 |
| H/Vi ratio (mole) | 0.8 | 0.9 | 0.8 | 0.8 | 0.8 | 0.8 |
| Evaluation | | | | | | |
| Viscosity (Pa · s @ 25° C., 1/s) | 42 | 42 | 59 | 58 | 35 | 32 |
| Viscosity (Pa · s @ 25° C., 10/s) | 15 | 14 | 20 | 20 | 16 | 17 |
| Thixotropic index | 3 | 3.04 | 3.0 | 2.9 | 2.1 | 1.9 |
| Refractive index | 1.55 | 1.55 | 1.55 | 1.55 | 1.55 | 1.55 |
| Transmittance (%) | 84 | 85 | 71 | 70 | 49 | 27 |
| Wettability on PCB | OK | OK | NG | NG | NG | NG |

As can be seen from the results from Tables 1 and 2, the embodiments of the curable silicone composition according to the present embodiments had enough thixotropic property and showed a higher transmittance property than the comparative example, indicating that the composition according to the present embodiments can provide cure products having a high transparency. Also, the curable silicone composition according to the present embodiments showed improved wettability on the PCB substrate providing reliable materials for semiconductor devices.

It can be therefore said that the curable silicone compositions according to the present embodiments are very useful for encapsulation applications in the manufacture of semiconductor packages, in particular LED packages.

1. A curable silicone composition, comprising:
(A) at least one resinous organopolysiloxane having at least two alkenyl groups and at least one aryl group per molecule;
(B) at least one organohydrogen polysiloxane having at least two silicon-bonded hydrogen atoms per molecule;
(C) at least one inorganic filler having a reflective index of 1.50 or higher;
(D) two or more polyether-modified organopolysiloxane comprising a combination of (d-1) at least one polyether-modified organopolysiloxane having at least one terminal —OH group in a polyether chain, and (d-2) at least one polyether-modified organopolysiloxane having at least one terminal alkoxy or acyloxy group in a polyether chain; and
(E) at least one hydrosilylation catalyst.

2. The curable silicone composition of claim 1, wherein the (A) resinous organopolysiloxane comprises aryl groups in the silicon atom-bonded organic groups in an amount of 30 mol % or more and 90 mol % or less relative to the total amount of the silicon atom-bonded organic groups.

3. The curable silicone composition of claim 1, wherein the (A) resinous organopolysiloxane consists of D siloxane units represented by (R₂SiO_{2/2}) and T siloxane units represented by (RSiO_{3/2}).

4. The curable silicone composition of claim 1, wherein the (B) organohydrogen polysiloxane comprises at least one aryl group in the silicon atom-bonded organic groups.

5. The curable silicone composition of claim 1, wherein the (C) inorganic filler is selected from aluminium oxides.

6. The curable silicone composition of claim 1, wherein the (D) polyether-modified organopolysiloxane including the (d-1) and (d-2) components is present in a total amount of 0.1% by weight or more and 10% by weight or less, relative to the total weight of the composition.

7. A sealing material formed from the curable silicone composition of claim 1.

8. An optical semiconductor device comprising the sealing material of claim 7.
